(19) United States
(12) Patent Application Publication
(10) Pub. No.: US 2015/0125279 A1
(43) Pub. Date: May 7, 2015

(54) SUBMERSIBLE PUMP COMPONENT AND METHOD OF COATING THEREOF

(71) Applicant: General Electric Company, Schenectady, NY (US)

(72) Inventors: Patrick James McCluskey, Latham, NY (US); Dennis Michael Gray, Delanson, NY (US); Scott Andrew Weaver, Ballston Lake, NY (US); Bala Srinivasan Parthasarathy, Bangalore (IN); Richard Arthur Nardi, JR., Scotia, NY (US); Charles Joseph Underwood, Shawnee, OK (US)

(73) Assignee: General Electric Company, Schenectady, NY (US)

(21) Appl. No.: 14/071,115

(22) Filed: Nov. 4, 2013

(51) Int. Cl. E21B 43/12; F04D 29/44; F04D 7/04; F04D 29/22; C23C 14/22; F04D 1/06

(52) U.S. Cl. CPC E21B 43/128; C23C 14/22; F04D 1/06; F04D 7/04; F04D 29/2294; F04D 29/445
USPC 415/199.2; 427/402; 427/255.23; 415/200

(57) ABSTRACT

A submersible pump component is provided. The component includes a substrate including an outer surface in a plurality of orientations, wherein a first portion of the outer surface is configured to be worn by a first wear mechanism, and a second portion of said outer surface is configured to be worn by a second wear mechanism. The component also includes at least one layer of a first coating applied to the outer surface, and at least one layer of a second coating applied over said first coating at said second portion of said outer surface. The first coating is configured to inhibit the first wear mechanism at the first portion of the outer surface, and the second coating is configured to inhibit the second wear mechanism at the second portion of the outer surface.

### BACKGROUND

The field of the present disclosure relates generally to oil and gas well assemblies and, more specifically, to a multi-layer coating selectively applied to surfaces of oil and gas well components.

At least some known submersible pumps are used in oil and gas wells, for example, to pump fluids from subterranean depths towards the surface. Submersible pumps that are electrically powered are generally referred to as electrical submersible pumps (ESPs). In operation, submersible pumps are submerged in the fluid to be pumped and use centrifugal forces to force the fluids from subterranean depths towards the surface. For example, at least some known submersible pumps utilize a series of stationary diffusers and rotating impellers to generate the centrifugal forces for forcing the fluids towards the surface.

Submersible pumps and the components thereof may be susceptible to corrosion and wear when operating for prolonged durations. For example, the operating environments of some known oil and gas well bores are such that the submersible pumps operating therein may be subjected to increased temperatures and pressures as the bores increase in subterranean depth. Moreover, the rotating components of submersible pumps may abrade over time, and particulates entrained in the fluid forced through the pumps may cause components of the pumps to gradually erode.

### BRIEF DESCRIPTION

In one aspect, a submersible pump component is provided. The component includes a substrate including an outer surface in a plurality of orientations, wherein a first portion of the outer surface is configured to be worn by a first wear mechanism, and a second portion of said outer surface is configured to be worn by a second wear mechanism. The component also includes at least one layer of a first coating applied to the outer surface, and at least one layer of a second coating applied over said first coating at said second portion of said outer surface. The first coating is configured to inhibit the first wear mechanism at the first portion of the outer surface, and the second coating is configured to inhibit the second wear mechanism at the second portion of the outer surface.

In another aspect, a submersible pump is provided. The pump includes a diffuser and an impeller coupled to the diffuser. At least one of the diffuser and the impeller includes an outer surface in a plurality of orientations, wherein a first portion of the outer surface is configured to be worn by a first wear mechanism, and a second portion of the outer surface is configured to be worn by a second wear mechanism. A multi-layer coating is applied to at least one of the diffuser and the impeller. The multi-layer coating includes at least one layer of a first coating applied to the outer surface and at least one layer of a second coating applied over the first coating. The first coating is configured to inhibit the first wear mechanism at the first portion of the outer surface, and the second coating is configured to inhibit the second wear mechanism at the second portion of the outer surface.

In yet another aspect, a method of coating a component of a submersible pump is provided. The method includes providing a first component that includes an outer surface in a plurality of orientations, wherein the first component is operable such that the outer surface is configured to be worn by a plurality of wear mechanisms. The method also includes determining a first portion of the outer surface configured to be worn by a first wear mechanism, determining a second portion of the outer surface configured to be worn by a second wear mechanism, forming at least one layer of a first coating to the outer surface, and forming at least one layer of a second coating over the first coating at the second portion of the outer surface. The first coating is configured to inhibit the first wear mechanism at the first portion of the outer surface, and the second coating is configured to inhibit the second wear mechanism at the second portion of the outer surface.

### DRAWINGS

These and other features, aspects, and advantages of the present disclosure will become better understood when the following detailed description is read with reference to the accompanying drawings in which like characters represent like parts throughout the drawings, wherein:

FIG. 1 is a perspective schematic illustration of an exemplary submersible pump system;

FIG. 2 is a perspective sectional illustration of an exemplary pump section that may be used with the submersible pump system shown in FIG. 1;

FIG. 3 is a schematic cross-sectional illustration of an exemplary pump stage that may be used in the pump section shown in FIG. 2, and taken along Area 3; and

FIG. 4 is a schematic cross-sectional illustration of an alternative pump stage that may be used in the pump section shown in FIG. 2, and taken along Area 4.

Unless otherwise indicated, the drawings provided herein are meant to illustrate features of embodiments of the disclosure. These features are believed to be applicable in a wide variety of systems comprising one or more embodiments of the disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

Embodiments of the present disclosure relate to oil and gas well components that may be used in a submersible pump assembly. More specifically, the oil and gas well components are fabricated from a substrate and a multi-layer coating applied to the substrate to facilitate increasing the service life of the components. For example, at least one layer of a first coating is applied to portions of an outer surface of the components that may be abraded during operation of the submersible pump, and at least one layer of a second coating is selectively applied over the first coating to portions of the components that may be eroded during operation of the submersible pump. The first and second coatings are specifically tailored to facilitate inhibiting abrasion and/or erosion to the components, and the first and second coatings are selectively applied to portions of the components most susceptible to the predetermined wear mechanism. As such, the oil and gas well components described herein facilitate increasing the service life of an associated submersible pump, facilitate increasing service intervals of the submersible pump, and thus result in the submersible pump being less-costly to operate when compared to other known alternatives.

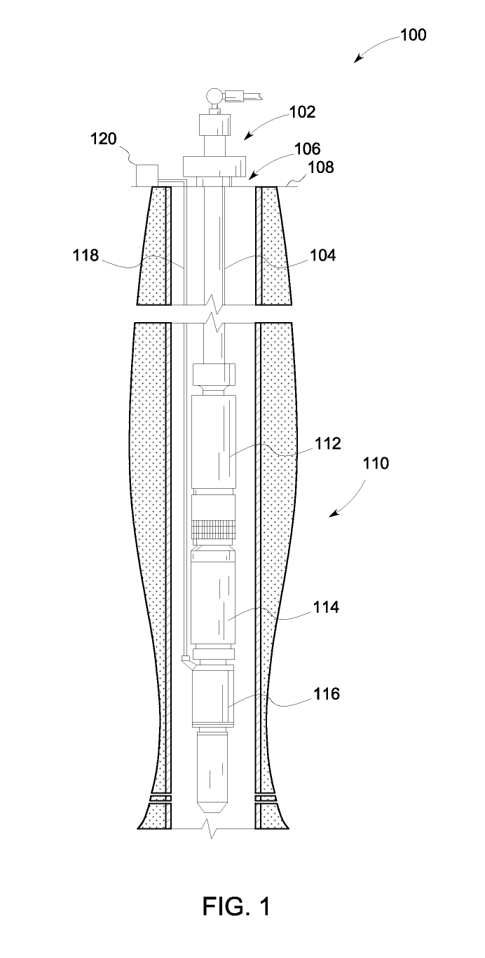

FIG. 1 is a perspective schematic illustration of an exemplary submersible pump system 100. In the exemplary embodiment, system 100 includes a well head 102, production tubing 104 coupled to well head 102, and an electrical submersible pump (ESP) 110 coupled to production tubing 104 and positioned within a well bore 106. Well bore 106 is drilled through a surface 108 to facilitate the production of subterranean fluids such as, but not limited to, water and/or petroleum fluids. As used herein, “petroleum fluids” may refer to mineral hydrocarbon substances such as crude oil, gas, and combinations thereof

ESP 110 includes a pump section 112, a seal section 114, and a motor 116. Motor 116 receives power through a power supply cable 118 coupled to a surface mounted power supply source 120. A shaft (not shown in FIG. 1) is coupled between motor 116 and pump section 112, and motor 116 drives pump section 112 to direct subterranean fluids towards surface 108. Seal section 114 facilitates shielding motor 116 from mechanical thrust produced by pump section 112, and allows for expansion of lubricating fluid during operation of motor 116.

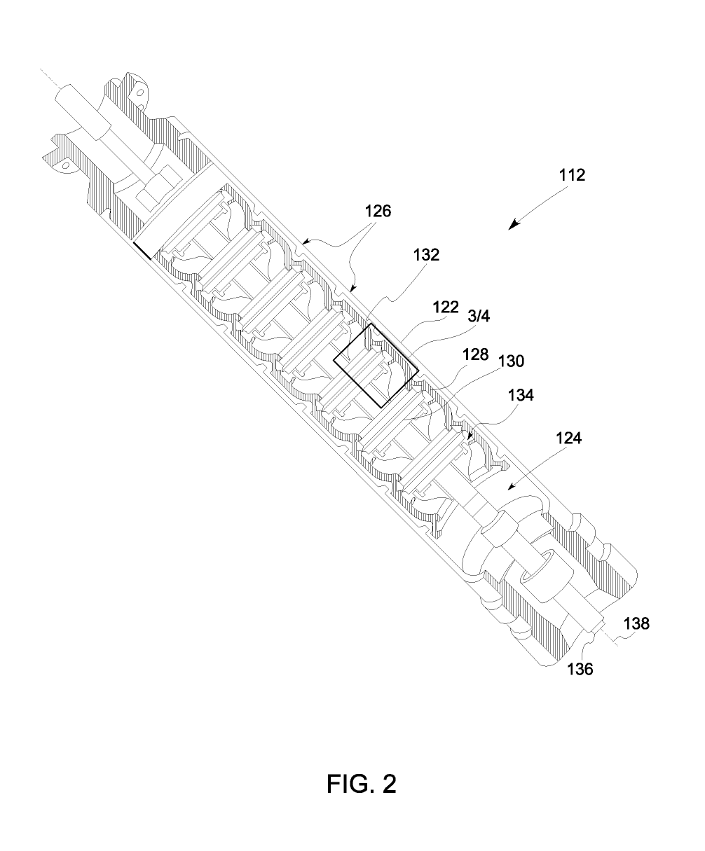

FIG. 2 is a perspective sectional illustration of an exemplary pump section 112 that may be used with ESP 110 (shown in FIG. 1). In the exemplary embodiment, pump section 112 includes an outer casing 122, an interior 124 of outer casing 122, and a series of pump stages 126 within interior 124. Pump stages 126 include a diffuser 128 and an impeller 130. More specifically, diffuser 128 is coupled to an interior surface 132 of outer casing 122, and impeller 130 is coupled to, and positioned within, diffuser 128 such that a passage 134 is defined therebetween. A rotating shaft 136 is coupled to impellers 130 and extends through interior 124 along a longitudinal axis 138 of pump section 112 to facilitate rotating impellers 130 relative to diffusers 128 during operation of pump section 112. While shown as including six pump stages 126, any number of pump stages may be used that enables pump section 112 to function as described herein.

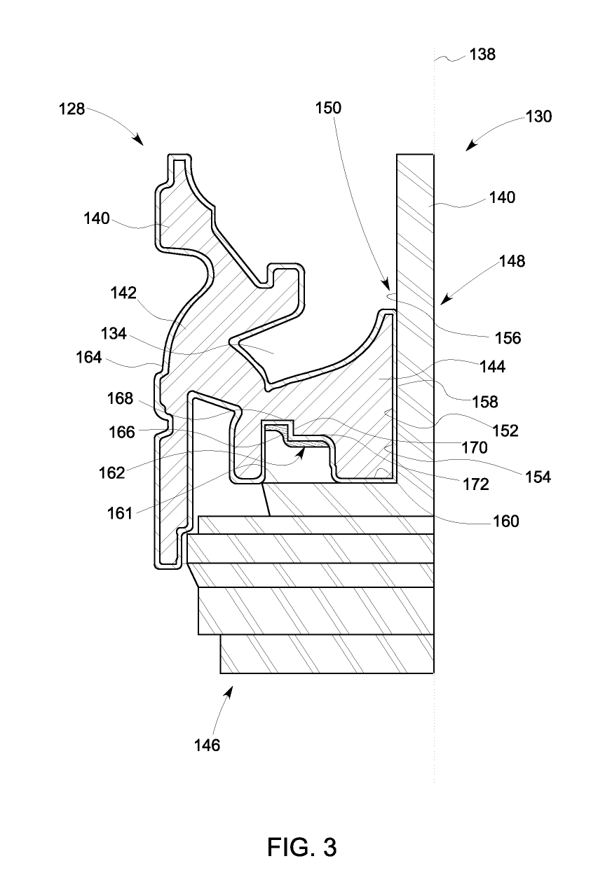

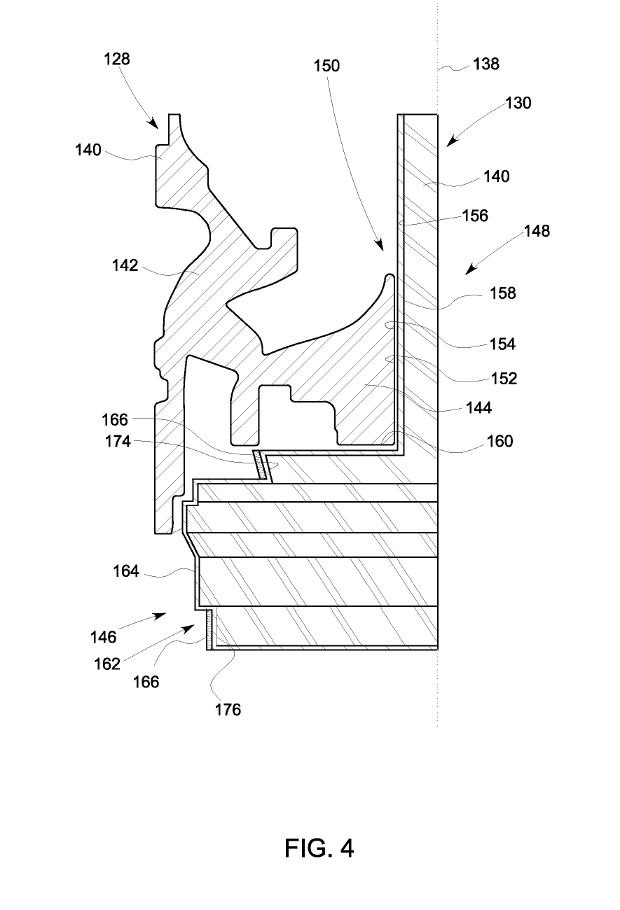

FIGS. 3 and 4 are schematic cross-sectional illustrations of an exemplary pump stage 126. In the exemplary embodiments, diffuser 128 is includes a substrate 140 having an outer radial portion 142 and an inner radial portion 144.

Impeller 130 includes a substrate 140 having a head portion 146 and a shaft portion 148 extending away from head portion 146. Shaft portion 148 is sized for insertion through an opening 150 defined in diffuser 128 by inner radial portion 144 such that shaft portion 148 and inner radial portion 144 are coupled together with an interference fit. Impeller 130 includes an outer surface 156, and diffuser 128 includes an outer surface 152. Outer surface 152 includes a first portion 154 and a second portion 160 of inner radial portion 144. Outer surface 156 includes a first portion 158 at shaft portion 148, and a second portion 161 at head portion 146. As such, first portion 154 of outer surface 152 presses against first portion 158 of outer surface 156 of impeller 130, and second portion 160 of outer surface 152 presses against second portion 161 of outer surface 156 of impeller 130.

In operation, certain areas of diffuser 128 and/or impeller 130 may be worn by predetermined accelerated wear mechanisms. For example, portions of outer surfaces 152 and 156 may be worn by a first wear mechanism (e.g., abrasion) and/or worn by a second wear mechanism (e.g., erosion). As used herein, “abrasion” refers to wear caused by rubbing contact between two surfaces (i.e., two-body abrasion) and/or rubbing contact caused by a third body positioned between two surface (i.e., three-body abrasion), and “erosion” refers to wear caused by impingement on a surface by particles entrained in fluid flow. For example, in operation, impeller 130 rotates relative to longitudinal axis 138 such that fluid is directed through passage 134 and towards surface 108 (shown in FIG. 1). As such, abrasion may occur between portions of outer surfaces 152 and 156 that are in contact with each other and/or may occur as a result of particles (not shown) positioned between outer surfaces 152 and 156. Moreover, particles entrained in the fluid flowing through passage 134 may cause erosion to different portions of outer surfaces 152 and 156.

Referring to FIG. 3, diffuser 128 includes a multi-layer coating 162 applied to substrate 140 to facilitate inhibiting abrasion and/or erosion to surfaces thereof In the exemplary embodiment, diffuser 128 has a geometry such that outer surface 152 has a plurality of orientations. Moreover, multi-layer coating 162 includes a first layer 164 of a first coating applied to the entire outer surface 152 of substrate 140, and a second layer 166 of a second coating selectively applied over first layer 164 to portions of outer surface 152 that may be eroded during operation of pump section 112. More specifically, second layer 166 is applied to a third portion 168, a fourth portion 170, and a fifth portion 172 of outer surface 152 of substrate 140 at inner radial portion 144. These portions of diffuser 128 are exposed to high-velocity fluid flow that includes particles entrained in the fluid flow. The high-velocity fluid flow is caused by pressure gradients in each pump stage 126 (shown in FIG. 2) and gaps between head portion 146 and diffuser 128. Alternatively, the first coating and the second coating may be selectively applied to any portion of diffuser 128 that enables pump section 112 to function as described herein.

Referring to FIG. 4, impeller 130 includes multi-layer coating 162 applied to substrate 140 to facilitate inhibiting abrasion and/or erosion to surfaces thereof In the exemplary embodiment, impeller 130 has a geometry such that outer surface 156 is in a variety of orientations. Moreover, multi-layer coating 162 includes first layer 164 of the first coating applied to the entire outer surface 156 of substrate 140, and second layer 166 of the second coating selectively applied over first layer 164 to portions of outer surface 156 that may be eroded during operation of pump section 112. More specifically, second layer 166 is applied to a first outer radial portion 174 and a second outer radial portion 176 of outer surface 156 of substrate 140 at head portion 146. These portions of impeller 130 are exposed to high-velocity fluid flow that includes particles entrained in the fluid flow. The high-velocity fluid flow is caused by pressure gradients in each pump stage 126 (shown in FIG. 2) and gaps between head portion 146 and diffuser 128. Alternatively, the first coating and the second coating may be selectively applied to any portion of impeller 130 that enables pump section 112 to function as described herein.

In alternative embodiments, both diffuser 128 and impeller 130 may include multi-layer coating 162 applied to respective substrates 140 thereof Moreover, multi-layer coating 162 may be applied to any oil and gas well component that enables ESP 110 to function as described herein.

Substrate 140 may be fabricated from any material that enables pump stage 126 (shown in FIG. 2) to function as described herein. An exemplary material used to fabricate substrate 140 includes, but is not limited to, an iron-based material. For example, the iron-based material may include a Ni-Resist alloy material.

The material used to fabricate the first coating and the second coating is selected based on the material's abrasion-resistance and erosion-resistance characteristics. For example, the material used to fabricate the first coating is selected to facilitate increasing the abrasion and/or corrosion resistance of substrate 140, and the material used to fabricate the second coating is selected to facilitate increasing the erosion-resistance of substrate 140. As such, first layer 164 facilitates inhibiting abrasion to first portions 154 and 158 along inner radial portion 144 and shaft portion 148, and second layer 166 facilitates inhibiting erosion to third portion 168, fourth portion 170, and fifth portion 172 (shown in FIG. 3) of inner radial portion 144. Second layer 166 also facilitates inhibiting erosion to first outer radial portion 174 and second outer radial portion 176 of head portion 146.

The first coating may be fabricated from any material that enables pump section 112 (shown in FIG. 2) to function as described herein. For example, the first coating may be fabricated from materials that facilitate adhering second layer 166 to substrate 140, and having a Taber Wear Index less than about 2.0 in accordance with ASTM G195. An exemplary material used to fabricate the first coating may include, but is not limited to, a combination of diamond particles and a composition including nickel and phosphorous. More specifically, in the exemplary embodiment, the combination includes between about 10 percent and about 40 percent diamond particles by volume, and the diamond particles have a size between about 0.5 microns (0.019 mils) and about 10 microns (0.39 mils). Moreover, the composition includes between about 99 percent and about 88 percent nickel by weight, and between about 1 percent and about 12 percent phosphorous by weight.

In the exemplary embodiment, first layer 164 is applied to substrate 140 using an electroless nickel phosphorous process. For example, a solution may be prepared that includes a soluble source of the materials used to form first layer 164. More specifically, the solution may be an aqueous solution including a soluble source of nickel ions, a soluble reducing agent (i.e., phosphorous), and diamond particles. The solution may also include a surfactant, complexing agents, and stabilizers to facilitate controlling the autocatalytic plating process. Substrate 140 may then be submerged in the aqueous solution such that each exposed portion of outer surfaces 152 and/or 156 is contacted by the aqueous solution. Substrate 140 remains in the aqueous solution for a period of time such that first layer 164 is formed on substrate 140 at any thickness that enables pump section 112 to function as described herein. In an alternative embodiment, the process used to form first layer 164 on substrate 140 may be based on the materials used to form the first coating.

The second coating may be fabricated from any material that enables pump section 112 (shown in FIG. 2) to function as described herein. For example, second layer 166 may be fabricated from materials having an erosion rate less than about 0.2 milligrams per minute in accordance with ASTM G76-95. An exemplary material used to fabricate second layer 166 may include, but is not limited to, a titanium-based material. More specifically, in the exemplary embodiment, the titanium-based material includes a titanium aluminum nitride material. Alternatively, second layer 166 may also be formed from silicon, boron, and/or elemental transition metals.

In the exemplary embodiment, second layer 166 is formed over first layer 164 via a physical vapor deposition process. For example, a cathode (not shown) may be formed from the second coating material (i.e., a titanium aluminum alloy material), and the cathode and the coated substrate 140 may be positioned within a vacuum chamber enclosure (not shown). A vacuum is drawn in the interior of the vacuum chamber enclosure, and current is supplied to the cathode to form an arc on the outer surface thereof The current supplied to the cathode facilitates vaporizing the coating material, and the vaporized coating material is directed towards substrate 140 in a nitrogen gas environment. As such, a titanium aluminum nitride second coating 166 may be selectively applied to line of sight portions of outer surfaces 152 and 156 of substrates 140.

The oil and gas well components described herein facilitate improving the service life of a submersible pump, for example. More specifically, a multi-layer coating is applied to the oil and gas well components to facilitate inhibiting predetermined wear mechanisms to the components. For example, portions of the components may be abraded by other components of the submersible pump, and other portions of the components may be eroded by particles entrained in fluid flow. Each layer of the multi-layer coating is tailored to inhibit at least one of the predetermined wear mechanisms. As such, the multi-layer coating facilitates reducing wear to the oil and gas well components.

An exemplary technical effect of the methods, systems, and assembly described herein includes at least one of (a) improving the service life of oil and gas well components; (b) reducing down time for submersible pumps using the oil and gas well components; and (c) selectively applying a multi-layer coating to portions of the oil and gas well components known to be susceptible to predetermined wear mechanisms.

Exemplary embodiments of the multi-layer coating applied to an oil and gas well component are described above in detail. The multi-layer coating is not limited to the specific embodiments described herein, but rather, components of systems and/or steps of the methods may be utilized independently and separately from other components and/or steps described herein. For example, the multi-layer coating may also be used in combination with other components other than oil and gas well components, and are not limited to practice with only the submersible pump as described herein. Rather, the exemplary embodiment can be implemented and utilized in connection with many applications where improving wear resistance of a component is desirable.

Although specific features of various embodiments of the present disclosure may be shown in some drawings and not in others, this is for convenience only. In accordance with the principles of embodiments of the present disclosure, any feature of a drawing may be referenced and/or claimed in combination with any feature of any other drawing.

This written description uses examples to disclose the embodiments of the present disclosure, including the best mode, and also to enable any person skilled in the art to practice embodiments of the present disclosure, including making and using any devices or systems and performing any incorporated methods. The patentable scope of the embodiments described herein is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A submersible pump component comprising:
a substrate comprising an outer surface in a plurality of orientations, wherein a first portion of said outer surface is configured to be worn by a first wear mechanism, and a second portion of said outer surface is configured to be worn by a second wear mechanism;
at least one layer of a first coating applied to said outer surface, wherein said first coating is configured to inhibit the first wear mechanism at said first portion of said outer surface; and
at least one layer of a second coating applied over said first coating at said second portion of said outer surface, wherein said second coating is configured to inhibit the second wear mechanism at said second portion of said outer surface.

2. The component in accordance with claim 1, wherein the first wear mechanism is abrasion by at least one of two-body and three-body abrasion, and the second wear mechanism is erosion by particles entrained in fluid flow.

3. The component in accordance with claim 1, wherein said first coating is formed from a combination of diamond particles and a composition including nickel and phosphorous.

4. The component in accordance with claim 3, wherein the combination comprises diamond particles within a range between about 10 percent and about 40 percent by volume of the combination.

5. The component in accordance with claim 3, wherein the composition comprises nickel within a range between about 99 percent and about 88 percent by weight of the composition.

6. The component in accordance with claim 1, wherein said first coating facilitates adhering said second coating to said substrate.

7. The component in accordance with claim 1, wherein said second coating is formed from a titanium-based material.

8. A submersible pump comprising:
a diffuser;
an impeller coupled to said diffuser, wherein at least one of said diffuser and said impeller comprise an outer surface in a plurality of orientations, wherein a first portion of said outer surface is configured to be worn by a first wear mechanism, and a second portion of said outer surface is configured to be worn by a second wear mechanism; and
a multi-layer coating applied to at least one of said diffuser and said impeller, said multi-layer coating comprising at least one layer of a first coating applied to said outer surface and at least one layer of a second coating applied over said first coating, wherein said first coating is configured to inhibit the first wear mechanism at said first portion, and said second coating is configured to inhibit the second wear mechanism at said second portion.

9. The pump in accordance with claim 8, wherein the first wear mechanism is abrasion by at least one of two-body and three-body abrasion, and the second wear mechanism is erosion by particles entrained in fluid flow.

10. The pump in accordance with claim 8, wherein said first coating is formed from a combination of diamond particles and a composition including nickel and phosphorous.

11. The pump in accordance with claim 8, wherein said second coating is formed from a titanium-based material.

12. The pump in accordance with claim 8, wherein said first coating is applied to each exposed portion of said outer surface.

13. A method of coating a component of a submersible pump, said method comprising:
providing a first component that includes an outer surface in a plurality of orientations, wherein the first component is operable such that the outer surface is configured to be worn by a plurality of wear mechanisms;
determining a first portion of the outer surface configured to be worn by a first wear mechanism;
determining a second portion of the outer surface configured to be worn by a second wear mechanism;
forming at least one layer of a first coating to the outer surface, wherein the first coating is configured to inhibit the first wear mechanism at the first portion of the outer surface; and
forming at least one layer of a second coating over the first coating at the second portion of the outer surface, wherein the second coating is configured to inhibit the second wear mechanism at the second portion of the outer surface.

14. The method in accordance with claim 13, wherein determining a first portion of the outer surface comprises determining the first portion of the outer surface configured to be abraded by a second component.

15. The method in accordance with claim 13, wherein determining a second portion of the outer surface comprises determining the second portion of the outer surface configured to be eroded by particles entrained in fluid flow.

16. The method in accordance with claim 13, wherein providing a first component comprises forming the first component from a substrate fabricated from a Ni-Resist alloy material.

17. The method in accordance with claim 13, wherein forming at least one layer of a first coating comprises submerging the first component in a solution including a soluble source of a first coating material.

18. The method in accordance with claim 17, wherein submerging the first component comprises submerging the first component in the solution including a soluble source of nickel ions, a soluble reducing agent, and diamond particles.

19. The method in accordance with claim 17, wherein submerging the first component comprises submerging the first component such that the first coating is applied to each exposed portion of the outer surface.

20. The method in accordance with claim 13, wherein forming at least one layer of a second coating comprises applying the at least one layer of the second coating to the second portion of the outer surface via physical vapor deposition.
